(19) United States
(12) Patent Application Publication
(10) Pub. No.: US 2023/0265317 A1
(43) Pub. Date: Aug. 24, 2023

(54) COVER TAPE AND ELECTRONIC COMPONENT PACKAGE

(71) Applicant: Denka Company Limited, Chuo-ku, Tokyo (JP)

(72) Inventors: Gosuke NAKAJIMA, Chuo-ku, Tokyo (JP); Keisuke NABA, Chuo-ku, Tokyo (JP); Takanori ATSUSAKA, Chuo-ku, Tokyo (JP); Hisatsugu TOKUNAGA, Chuo-ku, Tokyo (JP)

(73) Assignee: Denka Company Limited, Chuo-ku, Tokyo (JP)

(21) Appl. No.: 18/040,064

(22) PCT Filed: Aug. 18, 2021
(86) PCT No.: PCT/JP2021/030211

§ 371 Date: Jan. 31, 2023

(30) Foreign Application Priority Data
Aug. 24, 2020 (JP) 2020-140976

(51) Int. Cl. C09J 7/35; H01L 21/683; C09J 133/10

(52) U.S. Cl. CPC C09J 7/35; C09J 133/10; H01L 21/6836; C09J 2203/326

(57) ABSTRACT

This cover tape has at least a base layer and a heat seal layer, wherein the heat seal layer contains a polystyrene-based resin (A) and an ethylene-(meth)acrylic acid-based copolymer (B), and contents of the component (A) and the component (B) are more than 80 parts by mass and 95 parts by mass or less and 5 parts by mass or more and less than 20 parts by mass with respect to a total of 100 parts by mass of the component (A) and the component (B).

### TECHNICAL FIELD

The present invention relates to a cover tape and an electronic component package.

### BACKGROUND ART

Along with the miniaturization of electronic devices, the electronic components used are becoming smaller and having a higher performance. In the process of assembling electronic devices, components are automatically mounted on printed circuit boards. For transporting such electronic components for surface mounting, an electronic component package in which electronic components are accommodated in a carrier tape in which pockets are continuously thermoformed to match shapes of the electronic components is used to continuously supply the electronic components.

The electronic component package is manufactured by accommodating the electronic components in the pockets of the carrier tape, then stacking a cover tape having a heat seal layer as a cover material on an upper surface of the carrier tape and continuously heat sealing both ends of the cover tape in a longitudinal direction with a heated seal bar (for example, refer to Patent Literature 1).

### CITATION LIST

### Patent Literature

[Patent Literature 1] Japanese Unexamined Patent Publication No. 2010-173673

### SUMMARY OF INVENTION

### Technical Problem

In recent years, there has been significant miniaturization, lightening, and thinning of various electronic components such as capacitors, resistors, ICs, LEDs, connectors, switching elements, and the like, and the number of components mounted on substrates has also increased. Therefore, from the viewpoint of improving productivity with respect to electronic component packages, there is an increasing demand for high-speed sealing of the cover tape. Moreover, from the viewpoint of energy saving, reduction of energy required for heat sealing is required.

As a means of meeting these demands, lowering a softening temperature of the heat seal layer of the cover tape is conceivable, but in this case, as the softening temperature of the heat seal layer decreases, the tapes tend to stick to each other, and blocking tends to occur.

The present invention has been made in view of the above circumstances, and an object of the present invention is to provide a cover tape capable of being heat-sealed with less heat energy while occurrence of blocking is curbed, and an electronic component package using the same.

### Solution to Problem

In order to solve the above problems, one aspect of the present invention provides a cover tape including at least a base layer, and a heat seal layer, wherein the heat seal layer contains a polystyrene-based resin (A) and an ethylene-(meth)acrylic acid-based copolymer (B), and contents of the component (A) and the component (B) are more than 80 parts by mass and 95 parts by mass or less and 5 parts by mass or more and less than 20 parts by mass with respect to a total of 100 parts by mass of the component (A) and the component (B).

The cover tape is less likely to cause blocking and can be heat-sealed with less heat energy. Thus, while stoppage of a production line due to blocking is prevented, it is possible to perform the heat sealing at high speed and lower temperature, thereby improving productivity and saving energy in the manufacture of an electronic component package.

The component (A) may contain a copolymer of a styrene-based hydrocarbon and a conjugated diene-based hydrocarbon, and a high impact polystyrene. In this case, it becomes easy to ensure stable peel strength.

The component (B) may contain an ethylene-methyl methacrylate copolymer from the viewpoint of developing sealing properties with less heat energy and curbing blocking.

Another aspect of the present invention provides an electronic component package including a carrier tape having an accommodating portion, electronic components accommodated in the accommodating portion of the carrier tape, and the cover tape heat-sealed to the carrier tape as a cover material.

### Advantageous Effects of Invention

According to the present invention, it is possible to provide a cover tape capable of being heat-sealed with less heat energy while occurrence of blocking is curbed, and an electronic component package using the same.

### BRIEF DESCRIPTION OF DRAWINGS

FIG. 1 is a schematic cross-sectional view showing an embodiment of a cover tape.

FIG. 2 is a partially cutaway perspective view showing an embodiment of an electronic component package.

### DESCRIPTION OF EMBODIMENTS

Hereinafter, exemplary embodiments of the present invention are described in detail.

### Cover Tape

A cover tape of the present embodiment includes at least a base layer and a heat seal layer.

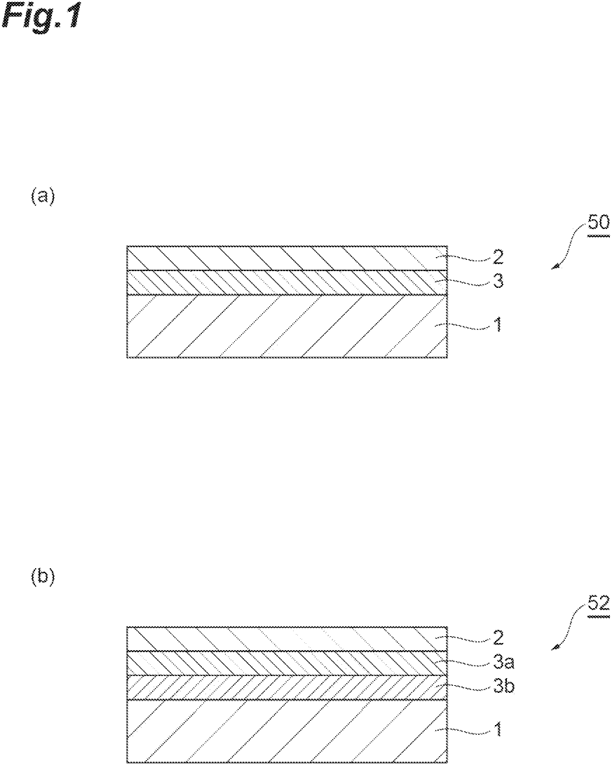

FIG. 1 is a schematic cross-sectional view showing an embodiment of a cover tape. The cover tape 50 shown in FIG. 1(a) includes a base layer 1, a heat seal layer 2 provided on one side of the base layer 1, and an intermediate layer 3 provided between the base layer 1 and the heat seal layer 2. Further, a cover tape 52 shown in FIG. 1(b) includes two intermediate layers 3a and 3b provided between the base layer 1 and the heat seal layer 2. The cover tape of the present embodiment may have a two-layer structure without the intermediate layer, and may have a structure in which a layer such as an antistatic layer is further provided on the side of the base layer 1 opposite to the heat seal layer 2, for example. In addition, the cover tape of the present embodiment may have a structure in which a layer such as an antistatic layer is further provided on the side of the heat seal layer 2 opposite to the base layer 1 as long as heat sealing properties of the heat seal layer are not impaired.

### Base Layer

The base layer may be a film formed from a resin composition containing one or more thermoplastic resins selected from a polyester resin such as polyethylene terephthalate and polyethylene naphthalate, a polyolefin-based resin such as polypropylene, a polyamide-based resin such as nylon, a polystyrene-based resin, a polyethylene-based resin and a polycarbonate resin. The films are preferably biaxially stretched films from the viewpoint of mechanical strength, and more preferably biaxially stretched polyethylene terephthalate films from the viewpoint of transparency and toughness.

Examples of the polystyrene-based resin include polymers having a styrene unit in a molecular chain at a molar ratio of ½ or more, such as polystyrene, high impact polystyrene (HIPS), styrene-butadiene copolymers or hydrogenated products thereof, styrene-isoprene copolymers or hydrogenated products thereof, graft copolymers of styrene and ethylene, styrene-butene-butadiene copolymers, and copolymers of methacrylic acid and styrene, and the like. The polymers may be used singly or in combination of two or more (as a mixture).

Examples of the polyethylene resin include those having an ethylene unit in the molecular chain at a molar ratio of ½ or more, such as low-density polyethylene, linear low-density polyethylene, ultra-low-density polyethylene, ethylene-α-olefin, ethylene-vinyl acetate copolymer, ethylene-(meth)acrylic acid copolymer, ethylene-methyl (meth)acrylate copolymer, ethylene-ethyl (meth)acrylate copolymer, and ethylene-propylene rubber. They can be used singly or in combination of two or more (as a mixture).

Various additives such as antioxidants and lubricants that are commonly used may be added to the base layer from the viewpoint of obtaining extrusion stability when a film is formed.

The base layer may be a single layer or may have a multilayer structure.

A thickness of the base layer may be 5 to 100 µm, 10 to 80 µm, or 12 to 30 µm from the viewpoint of mechanical strength and heat transfer during heat sealing.

### Intermediate Layer

The intermediate layer may be provided for the purpose of strengthening adhesive strength between the base layer and the heat seal layer and may include a thermoplastic resin. Examples of the thermoplastic resin include:
(i) a polyethylene resin such as low-density polyethylene, linear low-density polyethylene, and ultra-low-density polyethylene,
(ii) ethylene-1-butene, a copolymer of ethylene and unsaturated carboxylic acid, an ethylene-(meth)acrylic acid ester copolymer, an ethylene-vinyl acetate copolymer, and also a terpolymer with an acid anhydride, and a mixture thereof,
(iii) a styrene-ethylene graft copolymer, a styrene-propylene graft copolymer, a block copolymer of styrene-ethylene-butadiene, and a mixture thereof, and the like.

The thermoplastic resin is preferably a polyethylene-based resin, more preferably a low-density polyethylene resin or a linear low-density polyethylene resin, in view of the above purpose and easy layer formation.

Also, the intermediate layer may have a structure of two or more layers. In this case, due to production of a coextruded film of the heat seal layer and the intermediate layer, extrusion stability of the heat seal layer can be enhanced, while the adhesion between the coextruded film and the base layer can be improved by another intermediate layer. The intermediate layer having a structure of two or more layers may be, for example, a first intermediate layer in which the side in contact with the heat seal layer includes one or more of the resins shown in (i), (ii) and (iii) above, and may be a second intermediate layer in which the side in contact with the base layer includes one or more of the resins shown in (i) and (ii) above.

From the viewpoint of obtaining the extrusion stability during film formation, the intermediate layer may contain various additives such as antioxidants and lubricants that are commonly used.

A thickness of the intermediate layer may be 3 to 70 µm, 5 to 60 µm, or 10 to 50 µm, from the viewpoint of securing adhesive strength between the base layer and the heat seal layer and peel strength of the cover tape.

The cover tape of the present embodiment may have two or more base layers and/or intermediate layers. In such a cover tape, for example, the base layer and the intermediate layer may have a three-layer structure of a base layer, an intermediate layer and a base layer, or may have a four-layer structure of an intermediate layer, a base layer, an intermediate layer, and a base layer.

When the cover tape of the present embodiment has two or more base layers and/or intermediate layers, a known adhesive can be used to strengthen the adhesion between the layers. Examples of the adhesive include an isocyanate-based adhesive and an ethyleneimine-based adhesive. An adhesive layer preferably has a thickness of 5 µm or less from the viewpoint of preventing large variations in the peel strength of the cover tape.

### Heat Seal Layer

The heat seal layer can contain a polystyrene-based resin (A) (hereinafter, it may be referred to as a component (A)) and an ethylene-(meth)acrylic acid-based copolymer (B) (hereinafter, it may be referred to as a component (B)). A cover tape having such a heat seal layer makes it easy to ensure sealing properties with respect to a carrier tape made of various materials such as a carrier tape made of polystyrene and a carrier tape made of polycarbonate.

The heat seal layer may contain, as the component (A), a copolymer of a styrene-based hydrocarbon and a conjugated diene-based hydrocarbon, and a high impact polystyrene, and may contain a mixture thereof.

The styrene-based hydrocarbons include styrene, α-methylstyrene, and various alkyl-substituted styrenes. The conjugated diene-based hydrocarbons include butadiene and isoprene.

The heat seal layer may contain a styrene-butadiene copolymer and a high impact polystyrene as the (A) component and may contain a mixture thereof, from the viewpoint of easily stabilizing the peel strength of the cover tape.

The component (A) may contain a block copolymer (A-1) (hereinafter, it may be referred to as a component (A-1)) of 50% by mass or more and 95% by mass or less of styrene-based hydrocarbon and 5% by mass or more and 50% by mass or less of conjugated diene-based hydrocarbon, a block copolymer (A-2) (hereinafter, it may be referred to as a component (A-2)) of 10% by mass or more and less than 50% by mass of styrene-based hydrocarbon and more than 50% by mass and 90% by mass or less of conjugated diene-based hydrocarbon, and a high impact polystyrene (A-3) (hereinafter, it may be referred to as a component (A-3)) from the viewpoint of controlling the peel strength and the film formation. In this case, a proportional content of each of the components may be 20 to 40 parts by mass for the component (A-1), 35 to 60 parts by mass for the component (A-2), and 5 to 15 parts by mass for the component (A-3) with respect to a total of 100 parts by mass of the component (A-1), component (A-2) and component (A-3).

Examples of the ethylene-(meth)acrylic acid-based copolymer (B) include an ethylene-acrylic acid copolymer (EAA), an ethylene-methacrylic acid copolymer (EMAA), an ethylene-methyl methacrylate copolymer (EMMA), an ethylene-ethyl acrylate copolymer (EEA), an ethylene-methyl acrylate copolymer (EMA), and an ethylene-glycidyl methacrylate-methyl acrylate copolymer (EGMA-MA). The copolymers can be used singly or in combination of two or more (as a mixture).

The component (B) may have an ethylene content of 60 to 95% by mass, or 65 to 90% by mass, from the viewpoint of achieving sealing properties with less heat energy and suppressing blocking.

The heat seal layer may contain various additives such as antioxidants and lubricants that are commonly used, from the viewpoint of obtaining extrusion stability during film formation.

From the viewpoint of enabling heat sealing with less heat energy while suppressing the occurrence of blocking, the content of each of the components (A) and (B) in the heat seal layer may be more than 80 parts by mass and 95 parts by mass or less and 5 parts by mass or more and less than 20 parts by mass and may be 82 parts by mass or more and 95 parts by mass or less and 5 parts by mass or more and 18 parts by mass or less with respect to a total of 100 parts by mass of the components (A) and (B). In addition, from the viewpoint of delivery properties, the contents of the components (A) and (B) in the heat seal layer may be 84 parts by mass or more and 95 parts by mass or less and 5 parts by mass or more and 16 parts by mass or less and may be 85 parts by mass or more and 95 parts by mass or less and 5 parts by mass or more and 15 parts by mass or less with respect to a total of 100 parts by mass of the components (A) and (B).

The total content of the components (A) and (B) in the heat seal layer may be 50% by mass or more, may be 70% by mass or more, 90% by mass or more, or 100% by mass, based on a total amount of the heat seal layer.

Each of the layers described above can be formed into a film by, for example, a method such as an inflation method, a T-die method, a casting method, or a calendering method. In this case, each of the components constituting each of the layers may be incorporated using a mixer such as a Henschel mixer, a tumbler mixer, or a Mazelar, and may be directly formed into a film by an extruder, or the blend may be kneaded and extruded by a single-screw or twin-screw extruder to obtain pellets, and then the pellets may be further extruded by an extruder to form a film.

The heat seal layer may be formed by a method of forming a film by extrusion molding such as inflation molding or T-die extrusion, a method of dissolving the above-described component (A), and, if necessary, component (B) in a solvent and coating the film of the base layer, a method of coating as a water-based emulsion, or the like.

When a film for the heat seal layer is formed by extrusion molding, preferably, the film is co-extruded with the intermediate layer in order to improve the extrusion stability. For example, a two-layer film in which the intermediate layer and the heat seal layer are laminated can be obtained by melt-kneading a resin that forms the intermediate layer and a resin that forms the heat seal layer using separate single-screw or twin-screw extruders, laminating and integrating the two resins via a feed block or a multi-manifold die and then extruding from a T-die.

Moreover, the film for the heat seal layer obtained by extrusion molding may be laminated on the base layer by a general method such as dry laminating or extrusion laminating to form the cover tape.

An overall thickness of the cover tape may be 30 to 100 µm, may be 35 to 80 µm, and may be 40-70 µm. Within such a range, it becomes easy to ensure the strength and sealing properties of the tape.

The cover tape of the present embodiment is suitable for packaging electronic components. Examples of the electronic components include ICs, LEDs (light emitting diodes), resistors, liquid crystals, capacitors, transistors, piezoelectric element resistors, filters, crystal oscillators, crystal oscillators, diodes, connectors, switches, volumes, relays, inductors, and the like. The electronic components may be intermediate products using the components described above, or may be final products.

In the above applications, it is preferable to impart antistatic performance to the base layer and the heat seal layer in order to prevent dust attachment and to dissipate a charge of the cover tape itself. The antistatic performance can be imparted using a surfactant type, conductive metal oxide fine particles, or electron conductive polymer as a commonly used antistatic agent. Although the antistatic agent can be kneaded into the resin according to the performance to be expressed, both surface layers of the cover tape can be coated with the antistatic agent by a gravure coater or the like from the viewpoint of efficiently exhibiting effects.

The cover tape for packaging electronic components can be heat-sealed to a carrier tape, for example.

The carrier tape may have pockets for storing electronic components by a method such as air pressure molding or vacuum molding. As a material for the carrier tape, a material that can be easily formed into a sheet such as polyvinyl chloride (PVC), polystyrene (PS), polyester (A-PET, PEN, PET-G, PCTA), polypropylene (PP), polycarbonate (PC), polyacrylonitrile (PAN), acrylonitrile-butadienestyrene copolymer (ABS) can be used. The resins can be used singly or in combination. The carrier tape may be a laminate configured of multiple layers.

The cover tape of the present embodiment can be used in combination with a carrier tape such as a carrier tape made of polystyrene or a carrier tape made of polycarbonate.

### Electronic Component Package

An electronic component package of the present embodiment includes a carrier tape having an accommodating portion capable of accommodating electronic components, electronic components accommodated in the accommodating portion of the carrier tape, and a cover tape of the present embodiment heat-sealed to the carrier tape as a cover material.

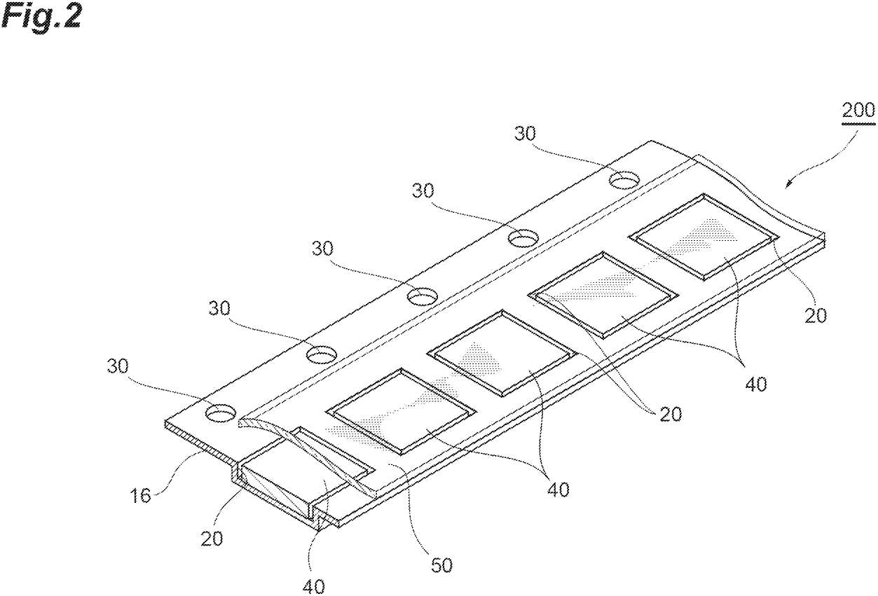

FIG. 2 is a partially cutaway perspective view showing one embodiment of the electronic component package. The electronic component package 200 shown in FIG. 2 includes an embossed carrier tape 16 having an accommodating portion 20, electronic components 40 accommodated in the accommodating portion 20, and a cover film 50 heat-sealed to the embossed carrier tape 16. Transport holes 30 that can be used for transporting various electronic components such as ICs in a sealing process are provided in the embossed carrier tape 16. Further, a hole (not shown) for electronic component inspection is provided in a bottom portion of the accommodating portion 20.

The electronic components and the carrier tape include those described above.

In the electronic component package of the present embodiment, a carrier tape wound into a reel shape can be used for storing and transporting the electronic components.

The electronic component package of the present embodiment can be manufactured by a method including a step of heat sealing the cover tape of the present embodiment to the carrier tape in which the electronic components are accommodated in the accommodating portion.

A member called a seal iron capable of applying a predetermined amount of heat and a predetermined pressure to the heat seal layer can be used in heat sealing of the cover tape. The cover tape can be heat-sealed to a surface of the carrier tape by pressing such a sealing iron onto the carrier tape from above the cover tape. As a specific method, a repeated sealing method in which the sealing iron is pressed a plurality of times while the embossed carrier tape is transported, or a continuous sealing method in which the heat sealing is performed while the sealing iron is continuously applied to the cover tape side can be applied.

A sealing temperature may be 100 to 240° C. or 120 to 220° C.

According to the above-described manufacturing method, the use of the cover tape of the present embodiment enables the heat sealing to be performed at high speed and low temperature, thereby improving productivity and saving energy in the manufacturing of the electronic component package.

### EXAMPLES

Hereinafter, the present invention will be described in more detail with reference to examples and comparative examples, but the present invention is not limited to the following examples.

### Example 1

As the polystyrene-based resin, 35 parts by mass of styrene-butadiene copolymer (manufactured by Denka Co., Ltd., product name “Clearen 170ZR”, styrene/butadiene mass ratio = 83/17), 55 parts by mass of styrene-butadiene copolymer (manufactured by JSR Corporation, product name “TR2000”, styrene/butadiene mass ratio = 40/60), 5 parts by mass of high-impact polystyrene (manufactured by Toyo Styrene Co., Ltd., product name “HIPS H870”), and as ethylene-(meth)acrylic acid-based copolymers, 5 parts by mass of ethylene-methyl methacrylate copolymer (manufactured by Sumitomo Chemical Co., Ltd., product name “Acryft WH303-F″, methyl methacrylate content: 18% by mass, ethylene content: 82% by mass) were kneaded in a twin-screw extruder to obtain a resin composition constituting a heat seal layer. A two-layer film (having a total thickness of 30 µm) including a first intermediate layer (having a thickness of 20 µm) and a heat seal layer (having a thickness of 10 µm) was obtained by co-extruding the above-described resin composition and a linear low-density polyethylene (manufactured by Ube Maruzen Polyethylene Co., Ltd., product name “Umerit 2040F”) as the first intermediate layer by a T-die method. This two-layer film was laminated with a biaxially stretched polyethylene terephthalate film (manufactured by Toyobo Co., Ltd., product name “Ester film E5100”, thickness of 16 µm) by an extrusion lamination method via a second intermediate layer (having of a thickness of 13 µm) made of a low-density polyethylene resin to obtain a cover tape of Example 1.

### Examples 2 to 8 and Comparative Examples 1 to 3

Cover tapes of Examples 2 to 8 and Comparative examples 1 to 3 were obtained in the same manner as in Example 1, except that the polystyrene-based resin and the ethylene-(meth)acrylic acid-based copolymer had compositions shown in Table 1.

The details of raw materials shown in Table 1 are as follows.
SBC: Styrene-butadiene copolymer (manufactured by Denka Co., Ltd., product name “Clearen 170ZR”, styrene/butadiene mass ratio = 83/17)
SBR: Styrene-butadiene copolymer (manufactured by JSR Corporation, product name “TR2000”, styrene/butadiene mass ratio = 40/60)
HIPS: High impact polystyrene (manufactured by Toyo Styrene Co., Ltd., product name “HIPS H870”)
EMMA: ethylene-methyl methacrylate copolymer (manufactured by Sumitomo Chemical Co., Ltd., product name “Acryft WH303-F″, methyl methacrylate content: 18% by mass, ethylene content: 82% by mass)
EGMA-MA: ethylene-glycidyl methacrylate-methyl acrylate copolymer (manufactured by Sumitomo Chemical Co., Ltd., product name “Bond First BF-7M”, glycidyl methacrylate content: 6% by mass, methyl acrylate content: 27% by mass, ethylene content: 67% by mass)
EMA: ethylene-methyl acrylate copolymer (manufactured by Japan Polyethylene Co., Ltd., product name “Rexpearl EB240H”, methyl acrylate content: 20% by mass, ethylene content: 80% by mass)
EEA: ethylene-ethyl acrylate copolymer (manufactured by Ube Maruzen Polyethylene Co., Ltd., product name “UBE polyethylene ZE735”, ethyl acrylate content: 19% by mass, ethylene content: 81% by mass)

The cover tapes of each of the examples and each of the comparative examples were evaluated by the following methods. Table 1 shows results thereof.

### Evaluation of Low-temperature Sealing Properties

A cover tape having a width of 21.5 mm was heat-sealed to a polystyrene carrier tape having a width of 24 mm (manufactured by Denka Co., Ltd., product name: “EC-R”) under conditions of a seal head width of 0.5 mm × 2, a seal head length of 24 mm, a seal pressure of 0.5 kgf, a transport length of 12 mm, a seal time of 0.3 seconds, and a seal iron temperature of 140° C. using a taping machine (manufactured by Nagata Seiki Co., Ltd., product name “NK-600”). Then, the peel strength is measured when the cover tape is peeled off at a peel angle of 170° to 180° and a peel rate of 300 mm per minute in an atmosphere having a temperature of 23° C. and a relative humidity of 50%, and low-temperature sealing properties was evaluated according to the following criteria.

### Determination Criteria

A: Peel strength is 0.2 N or more

C: Peel strength is less than 0.2 N

### Evaluation of Blocking Resistance

A record-wound cover tape having a width of 21.5 mm was left at rest in an atmosphere having a temperature of 23° C. and a relative humidity of 50% for 1 day, and is then unwound at a speed of 2000 mm per minute, and a load during unwinding was measured with a digital force gauge.

In addition, the cover tape was unwound by hand to confirm the presence or absence of blocking, and the blocking resistance was evaluated according to the following criteria.
A: No blocking
B: Blocking in some places
C: There is blocking as a whole

TABLE 1

| | | Example | Example 2 | Example 3 | Example 4 | Example 5 | Example 6 | Example 7 | Example 8 | Comparative Example 1 | Comparative Example 2 | Comparative Example 3 |
|---|---|---|---|---|---|---|---|---|---|---|---|---|
| Polystyrene -based resin | SBC | 35 | 35 | 35 | 35 | 35 | 35 | 35 | 35 | 35 | 35 | 25 |
| | SBR | 55 | 50 | 45 | 42 | 50 | 45 | 50 | 50 | 55 | 30 | 40 |
| | HIPS | 5 | 5 | 5 | 5 | 5 | 5 | 5 | 5 | 10 | 5 | 5 |
| Ethylene-(meth)acryli c acid-based copolymer | EMMA | 5 | 10 | 15 | 18 | - | - | - | - | - | 30 | 30 |
| | EGMA-MA | - | - | - | - | 10 | 15 | - | - | - | - | - |
| | EMA | - | - | - | - | - | - | 10 | - | - | - | - |
| | EEA | - | - | - | - | - | - | - | 10 | - | - | - |
| Total (parts by mass) | | 100 | 100 | 100 | 100 | 100 | 100 | 100 | 100 | 100 | 100 | 100 |
| low temperature sealing properties | Peel strength (N) | 0.22 | 0.26 | 0.33 | 0.38 | 0.22 | 0.27 | 0.28 | 0.23 | 0.18 | 0.31 | 0.23 |
| | Determinatio n | A | A | A | A | A | A | A | A | C | A | A |
| load during unwinding (mN) | | 78 | 84 | 91 | 95 | 82 | 88 | 86 | 80 | 72 | 110 | 138 |
| Blocking resistance | | A | A | A | B | A | A | A | A | A | C | C |

As shown in Table 1, it was confirmed that the cover tapes of Examples 1 to 8 can be heat-sealed with less heat energy while the occurrence of blocking is curbed.

On the other hand, the cover tape of Comparative Example 1 in which the heat seal layer does not contain an ethylene-(meth)acrylic acid-based copolymer has a low peel strength when sealing is performed at a low temperature, and the cover tapes of Comparative Examples 2 and 3 in which the content of the ethylene-(meth)acrylic acid-based copolymer in the heat seal layer exceeded the range of the present invention had a large load during unwinding, and the blocking also occurred.

### REFERENCE SIGNS LIST

1 Base layer
2 Heat seal layer
3, 3a, 3b Intermediate layer
16 Embossed carrier tape
20 Accommodating portion
30 Transport hole
40 Electronic component
50, 52 Cover tape
200 Electronic component package

1. A cover tape comprising:
at least a base layer, and a heat seal layer,
wherein the heat seal layer contains a polystyrene-based resin (A) and an ethylene-(meth)acrylic acid-based copolymer (B), and
contents of the component (A) and the component (B) are more than 80 parts by mass and 95 parts by mass or less and 5 parts by mass or more and less than 20 parts by mass with respect to a total of 100 parts by mass of the component (A) and the component (B).

2. The cover tape according to claim 1, wherein the component (A) contains a copolymer of a styrene-based hydrocarbon and a conjugated diene-based hydrocarbon, and a high impact polystyrene.

3. The cover tape according to claim 1, wherein the component (B) contains an ethylene-methyl methacrylate copolymer.

4. An electronic component package comprising:
a carrier tape having an accommodating portion;
electronic components accommodated in the accommodating portion of the carrier tape; and
a cover tape according to claim 1 heat-sealed to the carrier tape as a cover material.
